(19) United States
(12) Patent Application Publication
(10) Pub. No.: US 2008/0038910 A1
(43) Pub. Date: Feb. 14, 2008

(54) Multiple lithography for reduced negative feature corner rounding

(75) Inventor: Andrew Evert Carlson, Berkeley, CA (US)

Correspondence Address: MCDERMOTT WILL & EMERY LLP, 600 13TH STREET, N.W., WASHINGTON, DC, 20005-3096, US

(73) Assignee: ADVANCED MICRO DEVICES, INC.

(21) Appl. No.: 11/501,847

(22) Filed: Aug. 10, 2006

(51) Int. Cl. H01L 21/22; H01L 21/38

(52) U.S. Cl. 438/551

(57) ABSTRACT

Corner rounding of negative features is reduced by etching a targeted opening defined by the intersection of a hard mask opening and a photoresist mask opening. Embodiments include forming a hard mask over an underlayer in which the targeted opening is to be formed in a targeted area, forming a first opening in the hard mask layer exposing a first portion of the underlayer including part of the targeted area, forming a photoresist mask over the hard mask, the photoresist mask having a second opening exposing the targeted area of the substrate and part of the hard mask, and forming the targeted opening in the targeted area.

### FIELD OF THE INVENTION

The present invention relates to the fabrication of semiconductor devices having accurately formed design features. The present invention is particularly applicable to fabricating semiconductor devices having negative features in the deep sub-micron range without corner rounding.

### BACKGROUND ART

As the dimensions of semiconductor device features continue to shrink into the deep sub-micron range, as in the decananometer range, it becomes increasingly more difficult to form the features with high dimensional accuracy. This problem becomes particularly acute in forming negative features, such as contact holes, via holes, trenches, and microcavities. The minimum size of a feature depends upon the chemical and optical limits of a particular lithography system, and the tolerance for distortions of the shape, such as corner rounding when forming negative features in a layer or substrate. In forming small negative features, the degree of corner rounding can be high enough so that the negative feature is closed off, even when employing optical techniques. Conventional approaches to corner rounding have included ablation of pattern photoresist or definition of an inverse pattern to create a hard mask, on which the feature size can be further reduced by means of spatial lithography. These techniques have not proven completely successful.

Accordingly, a need exists for methodology enabling the fabrication of semiconductor chips comprising devices having accurately formed features in the deep sub-micron range, such as features less than 500 nm, such as 15 nm to 300 nm, e.g., 10 nm to 20 nm. There exists a particular need for such methodology enabling the accurate formation of negative features in various underlayers; e.g., dielectric layers, conductive layers and semiconductor substrates, with high efficiency and high manufacturing throughput.

### DISCLOSURE OF THE INVENTION

An advantage of the present invention is a method of fabricating semiconductor chips comprising devices having accurately formed features with dimensions in the deep sub-micron range.

Another advantage of the present invention is a method of fabricating semiconductor chips comprising devices having accurately formed negative sub-micron features with reduced corner rounding.

Additional advantages and other features of the present invention will be set forth in the description which follows and in part will be apparent to those having ordinary skill in the art upon examination of the following or may be learned from the practice of the present invention. The advantages of the present invention may be realized and obtained as particularly pointed out in the appended claims.

According to the present invention, the foregoing and other advantages are achieved in part by a method of fabricating a semiconductor chip, the method comprising: forming a hard mask over an underlayer in which a targeted opening is to be formed in a targeted area, the hard mask defining a first opening exposing a portion of the underlayer; forming a photoresist mask over the hard mask, the photoresist mask defining a second opening exposing the targeted area through a targeted mask pattern defined by part of the photoresist mask and by part of the hard mask; and forming the targeted opening in the targeted area.

Another advantage of the present invention is a method of fabricating a semiconductor chip, the method comprising forming an opening in an underlayer through a composite mask having a targeted mask pattern defined in part by an exposed portion of a hard mask and in part by an exposed portion of a photoresist mask.

A further advantage of the present invention is a method of fabricating a semiconductor chip, the method comprising forming an opening in an underlayer through a targeted mask pattern defined by the intersection of a hard mask opening and a photoresist mask opening.

Embodiments of the present invention include forming the hard mask, as by depositing, e.g., vapor deposition, a hard mask layer over the underlayer which may comprise any of various materials, such as dielectric materials, conductive materials, or a semiconductor substrate, forming a precursor photoresist mask over the hard mask layer, as by deposition or spinning, forming the first opening in the hard mask layer through the precursor photoresist mask, as by etching, and then removing the precursor photoresist mask. Embodiments of the present invention including forming the hard mask and photoresist mask employing any of various conventional deposition techniques.

Embodiments of the present invention further include forming the hard mask from an inorganic material, such as an oxide, a nitride, an oxynitride, or polycrystalline silicon. Embodiments of the present invention further include forming the targeted opening in the targeted area by etching using an etch recipe with high selectivity to the hard mask, as by etching with an etch recipe comprising carbon tetrafluoride (CF₄) using a nitride hard mask. Embodiments of the present invention include forming any of various types of negative features, such as contact holes, via holes, trenches for interconnects and STI structures.

Additional advantages of the present invention will become readily apparent to those skilled in the art from the following detailed description, wherein embodiments of the present invention are described, simply by way of illustration of the best mode contemplated for carrying out the present invention. As will be realized, the present invention is capable of other and different embodiments and its several details are capable of modifications in various obvious respects, all without departing from the present invention. Accordingly, the drawings and description are to be regarded as illustrative in nature, and not as restrictive.

### BRIEF DESCRIPTION OF THE DRAWINGS

FIGS. 1A through 1E are side sectional views schematically illustrating sequential phases of a method in accordance with an embodiment of the present invention.

FIGS. 2A through 2E are top-down views schematically illustrating sequential phases of the embodiment schematically illustrated in FIGS. 1A through 1E, respectively. In FIGS. 1A through 1E and 2A through 2E, similar features are denoted by like reference characters.

FIG. 3 is a top-down view schematically illustrating another embodiment of the present invention.

### DESCRIPTION OF THE INVENTION

The present invention addresses and solves problems attendant upon fabricating semiconductor devices comprising features with accurately formed dimensions in the decananometer range, particularly negative features up to 500 nm, such as 15 nm to 300 nm, e.g., 10 nm to 20 nm. These problems stem from dimensional restrictions imposed by the chemical and optical limits of conventional lithography systems, and distortions of feature shape, particularly corner rounding when forming negative features in a target substrate or underlayer. The present invention provides methodology enabling the formation of various types of semiconductor devices having such ultrafine features with high dimensional accuracy, in an efficient manner with increased manufacturing throughput.

In accordance with embodiments of the present invention, a multiple exposure, e.g., double exposure, technique is employed using plural masks, such as masks defining negative features. These plural masks are combined to define a smaller negative feature at the intersection of these masks.

Embodiments of the present invention comprises forming a thin hard mask or etch stop layer, such as an oxide, a nitride, an oxynitride, or polycrystalline silicon, e.g., silicon nitride, on a substrate or underlayer in which a negative feature is to be formed. Lithography is performed using a precursor photoresist mask to form a pattern in the hard mask layer, as by etching in a conventional manner, followed by removal of the precursor photoresist mask. Subsequently, another lithography step is implemented employing a second photoresist mask forming a composite mask exposing a portion of the substrate to be etched to the desired depth. The portion of the substrate to be etched or targeted area is defined in part by the hard mask layer and in part by the second photoresist mask, thereby permitting etching only in the area defined by the intersection of the hard mask and photoresist mask.

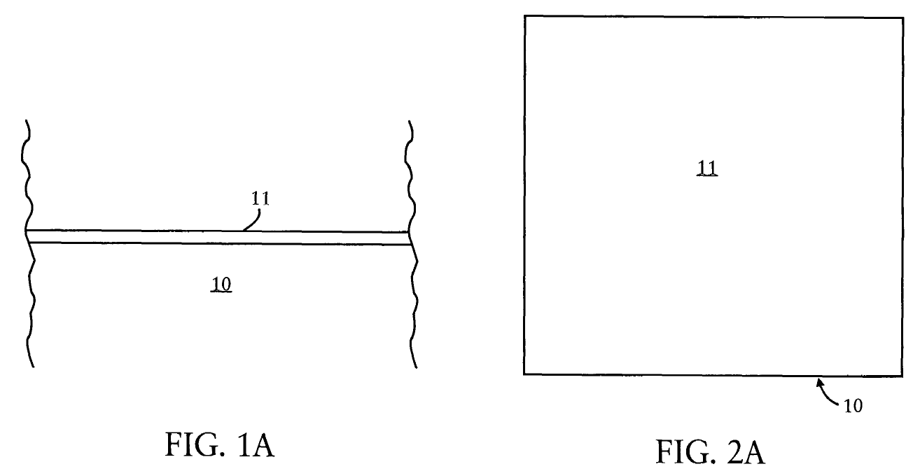

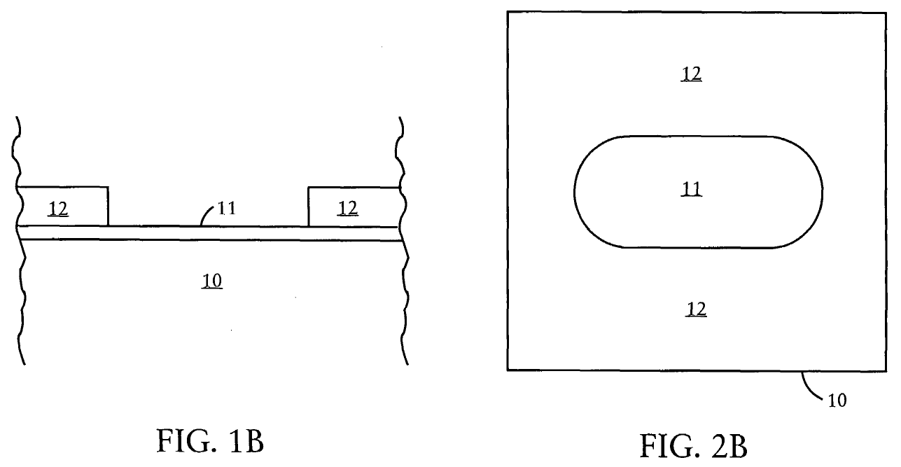

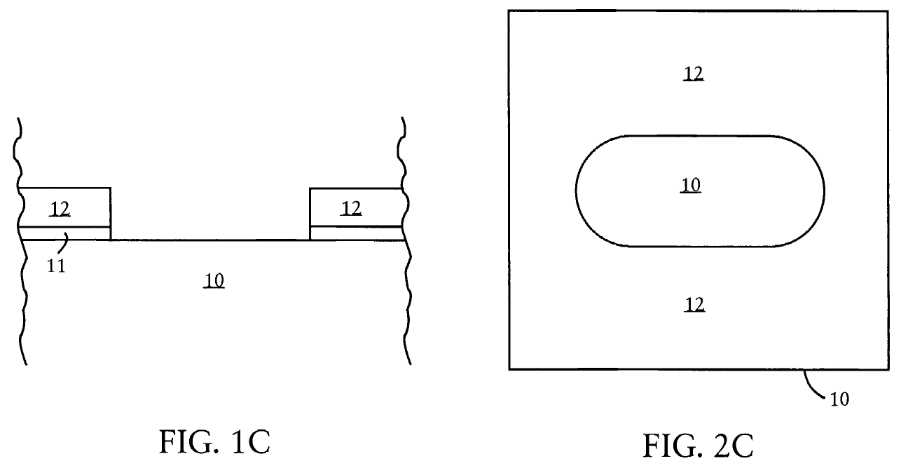

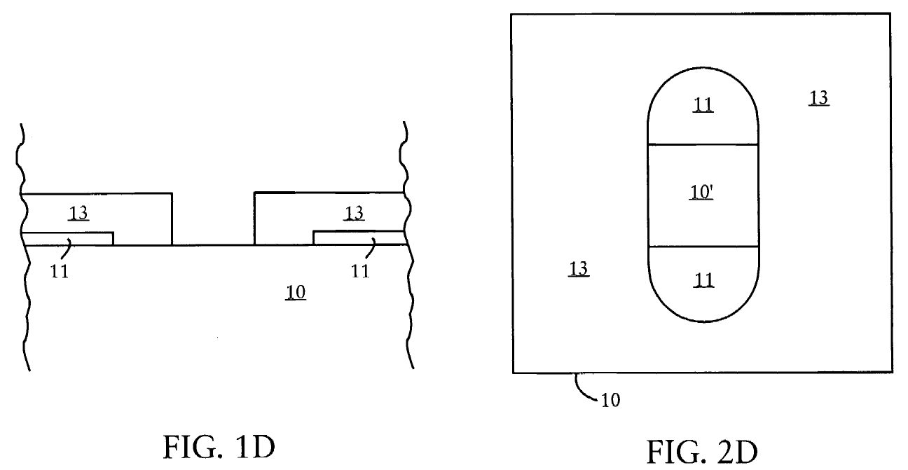

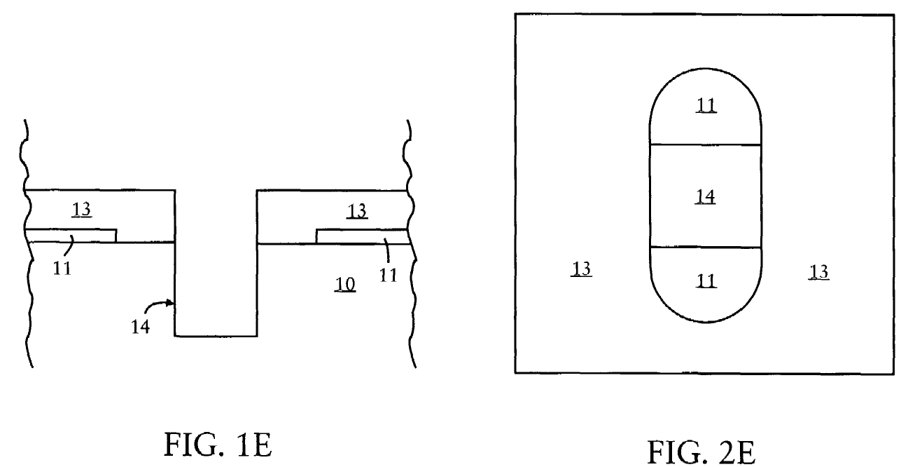

An embodiment of the present invention is schematically illustrated in FIGS. 1A through 1E (side section views) and 2A through 2E (top-down views) respectively. Adverting to FIGS. 1A and 2A, a hard mask layer 11 is formed on underlayer 10. Hard mask 11 can be any of conventional hard mask materials, such as an oxide or silicon nitride. The thickness of the hard mask layer can be selected depending upon its particular selectivity with respect to the etching recipe subsequently employed to etch the underlayer. For example, a silicon nitride hard mask layer can be formed at a thickness of about 10 nm to about 20 nm using an etching recipe comprising Cl₂ for etching silicon, e.g., to 300 nm. Substrate 10 can be a semiconductor substrate or any of various conventional dielectric layers, as when forming an interconnect pattern therein by etching a trench and/or via using damascene techniques.

Adverting to FIGS. 1B and 2B, a precursor photoresist mask 12 is formed over hard mask layer 11 defining a first mask pattern or opening, exposing a portion of hard mask layer 11. Photoresist mask 12 can be any of conventional photoresist materials and can be deposited in any conventional manner.

Adverting to FIGS. 1C and 2C, hard mask layer 11 is etched using photoresist mask 12, as by plasma etching using an etching recipe with high selectivity to substrate 10. For example, using a plasma etching recipe containing SF₆ or HBr.

Subsequently, as illustrated in FIGS. 1D and 2D, a second photoresist mask 13 is formed over a portion of hard mask 11 and on substrate 10. Photoresist mask 13 can comprise any of conventional photoresist materials and can be deposited in any conventional manner. Upon formation of photoresist mask 13, a composite mask is formed exposing a targeted area 10′ of the substrate 10 defined by the intersection of the photoresist mask 11 and photoresist mask 13. As show in top-down view of FIG. 2D, the composite mask, which exposes the targeted area 10′ of the substrate 10, comprises a lower hard mask 11 directly on substrate 10 and an upper photoresist mask 13 formed in part directly on part of lower photoresist mask 11 and formed in part directly on substrate 10.

Subsequently, and adverting to FIGS. 1E and 2E, etching is conducted through the composite mask to form negative feature 14 in underlayer 10, at a depth consistent with design requirements, such as at about 20 nm to about 200 nm, as by plasma etching using a CF₄ or CHF₃ plasma with high selectivity to the hard mask layer 11, e.g., silicon nitride.

In accordance with embodiments of the present invention, the use of a targeted mask pattern defined by the intersection of a hard mask and a photoresist mask greatly reduces the rounding of corner portions of negative features. The exact mechanism involved in the reduction of corner rounding of negative features is not understood with certainty. However, it is believed that the reduction in corner rounding stems from the formation of corners defined by at least one side surface of a hard mask material during etching.

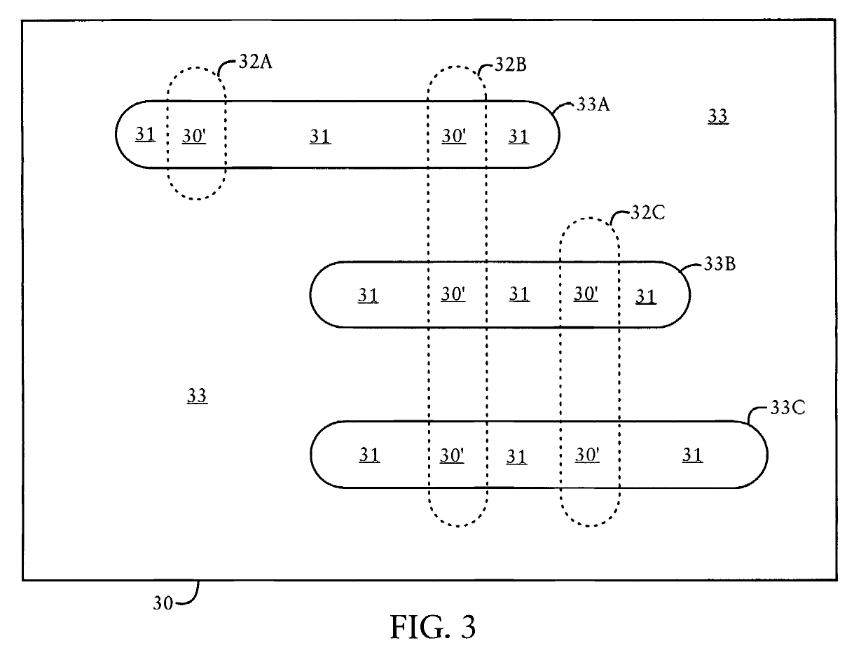

Embodiments of the present invention are not confined to forming either negative features or features circumventing the minimum feature size capable of being achieved by conventional photolithographic and etching techniques. Further, in accordance with embodiments of the present invention, shapes of the negative features may be extended in different directions, such as in orthogonal directions. FIG. 3 illustrates the formation of features of a larger size, thereby allowing for an expanded process window for each etching step. On the other hand, the extension of features in orthogonal directions, as shown in FIG. 3, can be formed at a minimum size, thereby allowing for smaller feature sizes. Embodiments of the present invention comprise extending the features defined by the first precursor photoresist mask and, hence, the mask pattern in the hard mask layer, all in the same direction or in varying directions, and extending the complimenting features of the photoresist mask in a direction orthogonal thereto.

In another embodiment of the invention, as shown in FIG. 3, the features are extended in orthogonal directions. For example, a hard mask layer 31 is formed on substrate 30. Employing a first precursor photoresist mask, openings 32A, 32B and 32C are formed in mask layer 31 exposing a portion of substrate 30. After removal of the first precursor photoresist mask, a photoresist mask 33 is formed defining openings 33A, 33B and 33C, substantially orthogonal to openings 32A, 32B and 32C, exposing targeted areas 30′ of substrate 30 to be etched through defined by intersections of the hard mask 31 and photoresist mask 33.

Embodiments of the present invention including forming various types of negative features, including microcavities which enjoy utility in forming photonic crystals, releasable MEMS structures, or integrated biological sensors. Various embodiments include forming microcavities in a semiconducting substrate and leaving the microcavities empty, i.e., leaving them filled with air or under vacuum. The microcavities can also be filled with an insulating material. Such microcavities can be formed in any size, e.g., at a depth of about 1 to about 10 μm.

The present invention can be employed in the fabrication of semiconductor chips comprising any of various types of semiconductor devices, including semiconductor memory devices, such as eraseable, programmable, read-only memories (EPROMs), electrically eraseable programmable read-only memories (EEPROMs), and flash eraseable programmable read-only memories (FEPROMs). Semiconductor chips fabricated in accordance with embodiments of the present invention can be employed in various commercial electronic devices, such as computers, cellular telephones and digital cameras, and can easily be integrated with printer circuit boards in a conventional manner.

The present invention enables the fabrication of semiconductor chips comprising devices with accurately formed features in the deep sub-micron range, particularly negative features with reduced corner rounding. The present invention enjoys industrial applicability in fabricating semiconductor chips useful in any of various types of industrial applications, including chips having highly integrated semiconductor devices, including flash memory semiconductor devices exhibiting increased circuit speed.

In the preceding description, the present invention is described with reference to specifically exemplary embodiments thereof. It will, however, be evident that various modifications and changes may be made thereto without departing from the broader spirit and scope of the present invention, as set forth in the claims. The specification and drawings are, accordingly, to be regarded as illustrative and not as restrictive. It is understood that the present invention is capable of using various other combinations and embodiments and is capable of any changes or modifications within the scope of the inventive concept as expressed herein.

What is claimed is:

1. A method of fabricating a semiconductor chip, the method comprising:
forming a hard mask over an underlayer in which a targeted opening is to be formed in a targeted area, the hard mask defining a first opening exposing a portion of the underlayer;
forming a photoresist mask over the hard mask, the photoresist mask defining a second opening exposing the targeted area through a targeted mask pattern defined by part of the photoresist mask and by part of the hard mask; and
forming the targeted opening in the targeted area.

2. The method according to claim 1, comprising forming the hard mask by:
forming a hard mask layer over the underlayer;
forming a precursor photoresist mask over the hard mask layer;
forming the first opening in the hard mask layer through the precursor photoresist mask; and
removing the precursor photoresist mask.

3. The method according to claim 1, comprising forming the hard mask from an oxide, a nitride, an oxynitride or polycrystalline silicon.

4. The method according to claim 3, comprising forming the hard mask from silicon nitride.

5. The method according to claim 4, wherein the underlayer comprises an oxide.

6. The method according to claim 5, comprising forming the first opening in the hard mask by plasma etching using an etch recipe comprising SF₆ or HBr.

7. The method according to claim 6, comprising etching the underlayer by plasma etching with an etch recipe comprising CF₄ or CHF₃.

8. The method according to claim 1, comprising forming the targeted opening in the underlayer by etching with high selectivity to the hard mask.

9. The method according to claim 5, comprising filling the targeted opening with conductive material.

10. The method according to claim 1, wherein the underlayer comprises a semiconductor substrate.

11. The method according to claim 10, wherein the targeted opening is a microcavity, the method further comprising filling the microcavity with air, leaving the microcavity under vacuum, or filling the microcavity with insulation material.

12. The method according to claim 1, comprising forming the hard mask at a thickness up to 500 nm.

13. The method according to claim 1, wherein:
the targeted mask pattern comprises a corner defined by first and second sides; and
the first or second side is defined by the hard mask.

14. A method of forming a device comprising:
fabricating a semiconductor chip according to claim 1; and
integrating the semiconductor chip with at least another component to form the device.

15. The method according to claim 14, comprising integrating the semiconductor chip with a printed circuit board.

16. A method of fabricating a semiconductor chip, the method comprising forming an opening in an underlayer through a composite mask having a targeted mask pattern defined in part by an exposed portion of a hard mask and in part by an exposed portion of a photoresist mask.

17. The method according to claim 16, wherein:
the targeted mask pattern comprises a corner defined by first and second sides; and
the first or second side is defined by part of the hard mask.

18. The method according to claim 16, comprising forming the opening by plasma etching the underlayer using an etch recipe with high selectivity to the hard mask.

19. A method of fabricating a semiconductor chip, the method comprising forming an opening in an underlayer through a targeted mask pattern defined by the intersection of a hard mask opening and a photoresist mask opening.

20. The method according to claim 19, wherein the mask pattern comprises at least one corner formed by a first side comprising an exposed hard mask material and a second side formed by an exposed photoresist material.
